(19) United States
(12) Patent Application Publication
(10) Pub. No.: US 2024/0183891 A1
(43) Pub. Date: Jun. 6, 2024

(54) Urban underground space Resistivity Sensing System and Data Collection Method Based on Cloud-Edge-End Collaboration

(71) Applicant: Zhejiang University, Hangzhou (CN)

(72) Inventors: Jiaxin WANG, Hangzhou (CN); Bangbing WANG, Hangzhou (CN)

(21) Appl. No.: 18/436,970

(22) Filed: Feb. 8, 2024

(30) Foreign Application Priority Data
Aug. 11, 2021 (CN) 202110916736.3

(51) Int. Cl. G01R 27/16

(52) U.S. Cl. CPC G01R 27/16

(57) ABSTRACT

An urban underground space resistivity sensing system and data collection method based on cloud-edge-end collaboration is disclosed. Employing an advanced cloud-edge-end architecture design, data collection tasks are decentralized to distributed edge nodes and sensing nodes. Computational tasks intensive in data processing and data mining are deployed on a central cloud computing platform, ensuring real-time and efficient data collection. Simultaneously, a three-dimensional spatial arbitrarily distributed sensing network is jointly constructed with well structures in the ground. Leveraging favorable conditions such as embedded horizontal cables and longitudinally drilled holes on both sides of roads, the system flexibly deploys a three-dimensional resistivity sensing network traversing streets, addressing the limitations of singular surface exploration and achieving detailed imaging of subterranean targets beneath urban streets.

### TECHNICAL FILED

The present invention relates to the field of electrical survey technology, specifically to an urban underground space resistivity sensing system and data collection method based on cloud-edge-end collaboration.

### BACKGROUND

Urban underground engineering serves as the foundation and integral component of urban development, characterized by its concealed and invisible nature. With the acceleration of urbanization, the health and safety of urban underground structures directly affect the life and property safety of city residents. However, the rapid, effective, and non-destructive assessment of the health of underground structures remains a challenging task for urban management authorities. Currently, government departments focus on strengthening supervision during design and construction to ensure the quality of underground engineering construction. Yet, the long-term safety and durability of underground engineering are not only closely related to structural design and construction quality but also influenced by changes in the surrounding environment over time. The impact on underground structures and the surrounding environment is interrelated and progressive. Deformation of the geological layers around underground structures and changes in stress may affect or even damage these structures, leading to further damage through the alteration of soil properties and groundwater movement. Therefore, a comprehensive and systematic study is needed, considering underground space structures, surrounding geological environments, underground pipe network structures, human and traffic environments as an organic whole over time and space. The construction of a “transparent city” utilizing accumulated historical data from drilling, geophysical exploration, and other sources is a critical step in this process and a key foundation for the development of “smart cities” Utilizing emerging scientific and technological advancements to build a city's four-dimensional dynamic perception network is a necessary approach for the construction of “smart cities,” holding significant implications for urban modernization and the development of a livable environment.

Changes in underground structures and the surrounding geological environment correspondingly alter the physical parameters of underground media, such as density, elastic wave velocity, and resistivity. A dynamic underground sensing system that monitors these physical parameters is akin to installing dynamic “health checkup” sensors for the city's “body.” It enables real-time insight, perception, and monitoring of the dynamic changes in the city's underground pipe network and underground structures. When critical thresholds are reached, it triggers timely anomaly warnings, allowing rapid location of the anomaly through a distributed multi-sensor monitoring network for prompt intervention and protection of life and property safety. However, current urban underground sensing systems primarily employ contact sensors for in-situ measurements, focusing on parameters like temperature, groundwater levels, stress, and displacement. There is a lack of sensors with penetrating imaging capabilities for long-term, remote, and non-contact intelligent sensing.

Electrical resistivity tomography (ERT) is a multi-channel, array exploration technique developed based on conventional electrical survey. It requires the deployment of cables and electrodes only once to obtain a large amount of survey data, saving manpower and resources, improving data collection efficiency, and providing intuitive and easily interpretable imaging results. However, traditional Electrical resistivity tomography faces challenges and obstacles in long-term monitoring (intelligent sensing) of urban underground targets (such as road cavity collapses):
1. Complexity of the urban street environment: (1) The area beneath urban streets is densely populated with various utility networks such as electricity, water, and communication. The underground environment is extremely complex. (2) The ground conditions on either side of urban streets vary significantly, leading to severe electromagnetic interference. (3) Electrodes can only be placed along the narrow sides of urban streets, lacking the longitudinal spatial expansion required for the three-dimensional ERT array, making it challenging to arrange a regular measurement network on the ground. (4) Although wellbore resistivity imaging has higher resolution, it is limited to vertical detection and the measurement spacing between wells is constrained. The superiorities of surface and wellbore resistivity imaging have not been fully utilized, and a combined exploration of both is more advantageous in fully leveraging the strengths of resistivity imaging.
2. Existing resistivity sensing system designs are highly dependent on municipal facilities and constrained by the actual locations of municipal facilities, making it difficult to effectively exploit their flexibility. The existing design is also restricted by the limited channels of sensing node electrodes, resulting in few types of power supply and potential measurement combinations, significantly impacting the sensing imaging effect. Additionally, as power supply and potential measurement electrode combinations may belong to different sensing nodes, the time delay of the existing serial wired transmission network will have a significant impact on the synchronization of power supply and potential measurements, leading to delays and affecting data collection efficiency.
3. Resistivity sensing systems managed by a central control console with remote centralized control have inherent deficiencies: (1) All sensing nodes are centrally managed and dispatched through a single central control console, which may lead to network congestion and hindered command and data transmission due to network busyness, causing time delays, errors, and packet loss, jeopardizing real-time and reliable operation. (2) The massive data collected is stored centrally and processed in the central control console, placing high demands on the hardware and software of the central control console. This approach fails to fully utilize general public computing resources, leading to redundant construction, resource waste, and increased operating and maintenance costs for the system.
4. The primary feature of a smart sensing system is highly automated remote intelligent telemetry: unmanned automatic data collection, remote automatic data transmission and storage, automatic data processing, automatic analysis, prediction, and alarm. However, existing resistivity sensing systems still have significant gaps, focusing only on data collection and lacking the ability to extract and mine data information. They fall far short of smart sensing levels and lack artificial intelligence predictive analysis capabilities.

Therefore, it is necessary to redesign resistivity sensing systems to form a system with low dependence on municipal facilities. It should fully utilize general wireless IoT systems, edge clouds (edge storage and edge computing), and central clouds as general public resource platforms. Leveraging cutting-edge technologies such as big data and artificial intelligence is essential to create a smart sensing system with intelligent risk prediction and assessment capabilities.

### SUMMARY

To address the shortcomings of the existing technology, the present invention provides an urban underground space resistivity sensing system and data collection method based on cloud-edge-end collaboration. More specifically:

An urban underground space resistivity sensing system based on cloud-edge-end collaboration is provided. The system adopts an cloud-edge-end architecture design, including a central cloud computing platform, a plurality of edge servers connected to the central cloud computing platform through a distributed network, and a plurality of resistivity sensing nodes connected to each edge server through a distributed network.

The central cloud computing platform is configured to manage the entire resistivity sensing system, including: setting and configuring distributed edge servers; managing all resistivity sensing nodes through edge servers; performing global data processing and model inversion, including comparing and mining real-time and historical data, and sending model results to edge servers to guide initial data analysis; and reporting abnormal data exceeding thresholds.

The edge servers, as edge nodes, coordinate the collaborative work of multiple resistivity sensing nodes within their controlled domains, including: coordinating and controlling the selection and collection process of power supply and potential measurement electrode pairs within the domain; filtering, organizing, and storing domain data collected through data collection in the designed format, simultaneously uploading the data to the central cloud computing platform for backup; after data collection is complete, comparing and analyzing real-time data with historical data and the area model calculation results fed back by the central cloud computing platform based on historical data to detect anomalies; if abnormal changes are detected, reporting the anomaly information to the central cloud computing platform.

The resistivity sensing nodes are end nodes, and multiple resistivity sensing nodes are horizontally distributed along city roads and/or vertically arranged in vertical wells. Each resistivity sensing node is an independent resistivity sensor unit, including a collection station, a multi-channel electrode conversion switch connected to the collection station, a multi-core ERT cable, and a grounding electrode connected to the multi-core ERT cable. The resistivity sensing nodes, based on instructions from their corresponding edge nodes, perform power supply or potential measurement tasks as required and upload the measurement data to the corresponding edge node.

Furthermore, when resistivity sensing nodes are horizontally arranged along city roads, the cable in the resistivity sensing nodes is a segmented cascading ERT cable. The segmented cascading cable is connected in series through a cascading electrode conversion switch, forming a complete cable, and the collection station is connected to one end of the complete cable.

When resistivity sensing nodes are arranged along vertical wells, the cable in the resistivity sensing nodes is a single centralized ERT well cable. This cable evenly sets multiple electrode structures, with each electrode structure serving as a grounding electrode. The top of the cable is connected to the collection station through a centralized electrode switch.

When resistivity sensing nodes are jointly arranged along city roads and vertical wells, the single centralized ERT well cable in the well is initially connected to one end of the multi-core segmented cascading ERT cable on the ground through a centralized electrode conversion switch. The collection station is connected to the other end of the segmented cascading ERT cable. The centralized ERT cable has multiple electrode structures evenly spaced, with each electrode structure serving as a grounding electrode.

Furthermore, the collection station includes a control module, a power supply module, a potential measurement module, a communication module, and a GPS module.

The control module, under the command of its corresponding edge node, is configured to control the operation management, self-check, communication with the edge node, functional interchange between power supply/potential measurement under collection instructions, channel selection, execution of the collection process, and data storage and upload of the collection station's own system.

The power supply module, upon receiving a power supply command, is configured to select the corresponding electrode channel through the control module and supplies power to the underground through the connected cable channel and electrode, simultaneously measuring the power supply current magnitude. After power supply is completed, the module is configured to upload the node's and its power supply channel's identification, measurement start time, and power supply current value.

The potential measurement module, upon receiving a potential measurement command, is configured to select the corresponding electrode channel through the control module and conducts potential measurement through the connected cable channel and electrode. The potential measurement module is also configured to measure the potential difference magnitude. After measurement, the module is configured to upload the node's and its potential measurement channel's identification, measurement start time, and potential difference value.

The GPS module is configured for precise timing and coordination among nodes.

Furthermore, remote data transmission between edge nodes and end nodes occurs through mobile communication networks, while remote data transmission between edge nodes and the central cloud computing platform takes place through wired networks.

An urban underground space resistivity data collection method based on cloud-edge-end collaboration, implemented using the above system, includes the following steps:
(1) Determining the arrangement and collection parameters of resistivity sensing nodes based on the actual conditions of the target street, the maximum exploration depth, and the resolution of underground detection targets.
(2) Arranging resistivity sensing nodes on the target street. The central cloud computing platform assigns a unique system identification to each edge node, and each edge node assigns a unique system identification to each resistivity sensing node within its domain. The sensing nodes assign unique system identifications to each electrode point within their system, and collect the three-dimensional geographic coordinates of each electrode point.
(3) Sequentially selecting, by the central cloud computing platform, different edge nodes for block measurements; the selected edge node, in sequence according to the system identification of resistivity sensing nodes; selecting one sensing node as a power supply node, and then selecting one electrode combination within the sensing node as a power supply electrode pair AB, and selecting an electrode combination within the domain of the edge node belonging to the sensing node as a potential measurement electrode pair MN; wherein the potential measurement electrode pair MN belongs to a same sensing node; determining whether a distance between the measurement electrode pairs MN and AB is within an effective measurement radius r of AB; if yes, performing power supply and potential measurement; if no, moving to the next ABMN combination position for a new measurement condition judgment; the effective measurement radius of AB is given by r≤n·a, where n is the effective radius coefficient, n=6-14, and a is the distance between A and B; traversing all power supply electrode pairs and the plurality of paired potential measurement electrode pairs within the sensing node, and completing the power supply and potential measurement process when the sensing node acts as the power supply node.
(4) Sequentially moving to the next resistivity sensing node and performing the power supply and potential measurement process until all power supply electrode combinations for the last sensing node are completed, thereby finishing the entire power supply and potential measurement process for the current edge node.
(5) Proceeding to the next edge node and performing the same power supply and potential measurement process until all edge nodes have been traversed.
(6) After completing the data collection, the edge node notifies each sensing node to upload the collected data and its own status information. The edge node formats the data for its region, quickly compares it with the region model results downloaded from the central cloud computing platform, and provides processing analysis results. The edge node reports the preliminary processing and analysis results to the central cloud computing platform. The central cloud computing platform, based on historical data and intelligent analysis model results from other sources, feeds back and distributes the results to each edge node, guiding subsequent edge nodes in rapid anomaly analysis and risk identification.

Furthermore, when AB serves as the power supply electrode pair, and the GPS module coordinates the timed parallel measurement of potential measurement electrode pair MN which is positioned different nodes and satisfies conditions, namely, multiple potential measurement electrode pairs MN at different nodes parallelly work with one power supply electrode pair AB, and thus achieving One-Supply Multiple-Measurements simultaneously.

Furthermore, when selecting the power supply electrode pair AB, follow the principle of increasing electrode numbers and start from the end where the collection station is located. Choose the electrode A as the closest electrode point to the collection station and select the electrode B with a sequence number interval of 1 as the power supply electrode pair AB. Then, maintain the sequence number interval of AB, shift A and B to the next electrode point until point B reaches the last electrode point of the current sensing nodes, completing all power supply processes with AB sequence number interval equal to 1.

Then start from the beginning and select points A and B with a sequence number interval of 2 for power supply. Shift A and B until point B reaches the last electrode point, completing the power supply process with a sequence number interval of 2 between A and B.

Repeat the process, changing the interval between A and B until the set maximum isolation coefficient is reached, completing the power supply process for that sensing node.

Furthermore, once the resistivity sensing nodes are arranged, and the positions of each electrode point are fixed with accurate coordinates, the corresponding edge node calculates and creates a power supply and potential measurement collection table in advance. In this table, the sensing node number and electrode number of each power supply point AB, as well as the sensing node number and electrode number of multiple potential measurement points MN, are arranged in order. This ensures that the actual collection is executed in the order of the table, completing the entire data collection process.

Compared to the existing technology, the present invention has the following beneficial effects:
1. The “cloud-edge-end” architecture achieves hierarchical storage and processing of perception data. By deploying edge servers close to the collection end, the system achieves near-end, regional, and distributed data collection and storage, avoiding the impact of network congestion on the collection process, thereby enhancing the real-time and responsive efficiency of data collection. The “central cloud” leverages computational advantages for extensive data processing, data mining, and risk prediction. The use of the “cloud-edge-end” distributed and centralized collaborative architecture significantly enhances the capabilities and efficiency of the resistivity perception system.
2. The use of a multi-channel, arbitrarily distributed resistivity sensing node design with unlimited load capacity ensures the efficiency of connections between electrode channels and a high density of power supply/potential measurement combinations. It also minimizes the number of sensing nodes and remote transmission devices, reducing system construction costs.
3. The adoption of a well-ground joint construction establishes a three-dimensional spatial arbitrarily distributed sensing network. Taking advantage of favorable conditions such as buried horizontal cables and longitudinally drilled holes on both sides of the road, the system flexibly deploys a three-dimensional resistivity sensing network across streets, overcoming the limitations of single-surface exploration and achieving fine imaging of targets beneath the streets.
4. Remote intelligent perception is achieved through the combination of wireless mobile communication networks and wired public networks. Leveraging the zoning characteristics of mobile communication networks in urban areas automatically manages the segmentation and hierarchical management of the resistivity sensing network. The large capacity of mobile communication networks allows for an unlimited number of sensing nodes, providing flexibility and scalability to the sensing system. The automatic connection of mobile communication networks to the city's high-speed backbone network simplifies and enhances the feasibility of the cloud-edge-end-end design.
5. Through the combination of cloud computing platforms and artificial intelligence, the system achieves automated, intelligent processing, and mining of resistivity perception data, along with prediction and alerting. Utilizing existing artificial intelligence of things (AIoT) technology as a carrier for remote information transmission and data mining of the resistivity sensing network achieves intelligent analysis and prediction alerting for resistivity perception information.
6. Leveraging public communication networks and public computing resource platforms avoids redundant system construction and resource waste, while saving maintenance costs in the later stages. This approach allows the system construction to focus on front-end sensing node development, data collection methods, and system architecture design. Depending on the public Internet of Things construction, the system's performance will automatically upgrade with updates to the public Internet of Things system. Only the maintenance and upgrade of sensing node units are required, resulting in lower overall system investment and significantly enhanced system expansion capability and adaptability.

### BRIEF DESCRIPTION OF THE DRAWINGS

FIG. 1 is a schematic architecture diagram of the resistivity sensing system according to the present invention;

FIG. 2 is a schematic diagram of the structure of the collection station and cable connection according to the present invention;

FIG. 3 is a schematic diagram of the deployment method for the resistivity sensing system according to the present invention;

FIG. 4 is a schematic diagram of the resistivity sensing system electrode layout on both sides of the road and in the wellholes according to the present invention.

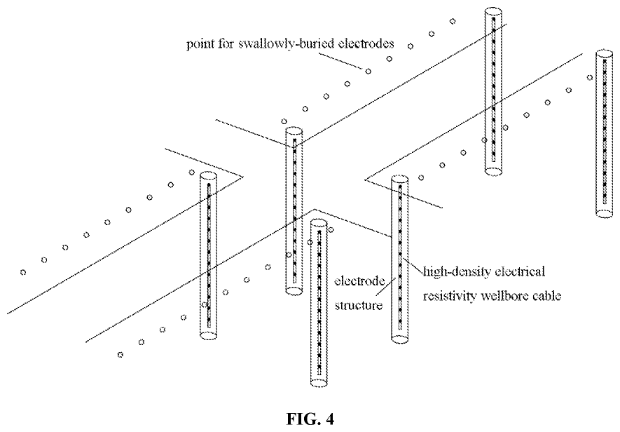

### DETAILED DESCRIPTION OF THE EMBODIMENTS

Following is a further explanation of the present invention with reference to the accompanying drawings.

### I. System Structure

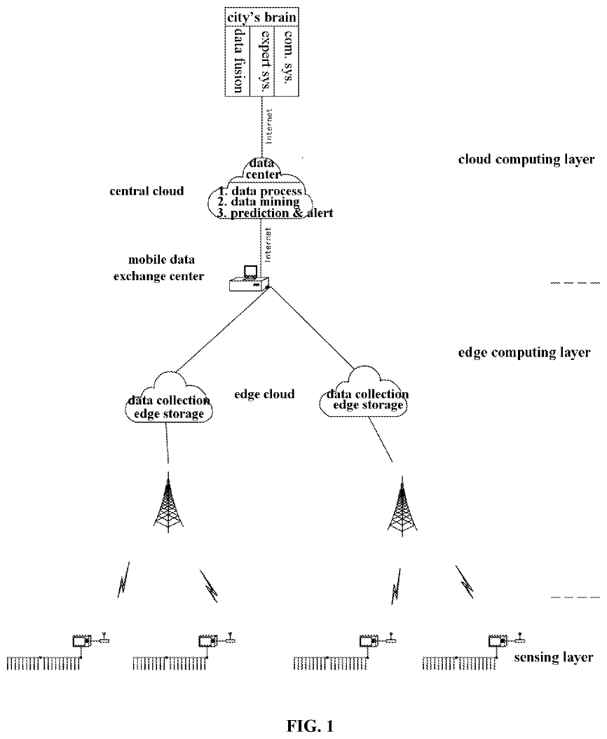

The resistivity sensing system with well-ground joint design is based on the “cloud-edge-end” architecture, including sensing nodes (i.e., end), edge cloud (i.e., edge) responsible for coordinating the data collection process near the sensing nodes, the central cloud computing platform (i.e., cloud) dedicated to centralized data processing and analysis, and wireless and wired transmission networks for cloud-edge-end connections. The system may be partitioned into three components: the sensing layer, the edge computing layer, and the central cloud computing layer (FIG. 1).

a. Sensing Layer

The sensing layer includes numerous resistivity sensing nodes arranged horizontally along both sides of urban roads or combined with vertical wellholes, creating a cross-street and well-ground resistivity joint imaging to achieve four-dimensional resistivity sensing of the area below the street.

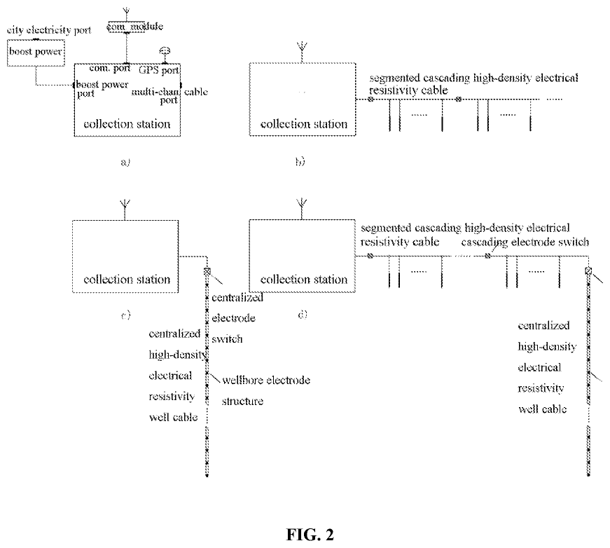

The resistivity sensing node is an independent resistivity sensor unit, including a collection station (as shown in FIG. 2a), a multi-channel electrode switch connected to the collection station, a multi-core ERT cable, and grounding electrodes connected to the multi-core ERT cable. ERT cable specifically refers to a multi-core cable with evenly spaced taps and conductive joints.

The resistivity sensing nodes can be arranged in the following three ways:

### (1) Horizontal Arrangement Along Urban Roads

In this case, the cable in the resistivity sensing node is a multi-core segmented cascading ERT cable. The segmented cascading ERT cable is serially connected through a cascading electrode switch. The collection station is connected to one end of the entire cable. The segmented cascading high-density cable carries 8-10 electrodes. The connection between the cable and the collection station is shown in FIG. 2b.

(2) Vertical Arrangement along Vertical Wells

In this case, the cable in the resistivity sensing node is a single cable with a one-piece molded centralized structure design to ensure water tightness. The cable is evenly equipped with multiple electrode structures, each serving as a grounding electrode. The top of the cable is connected to the collection station through a centralized electrode switch. The connection between the cable and the collection station is shown in FIG. 2c.

(3) Combined Arrangement along Urban Roads and Vertical Wells

In this case, the cable arranged in the wellhole is still a single cable with a centralized ERT structure. The cable is evenly equipped with multiple electrode structures, each serving as a grounding electrode. The horizontally arranged cable is a multi-core segmented cascading ERT cable. However, in this case, the single cable arranged in the wellhole is first connected to one end of the multi-core segmented cascading ERT cable through a centralized electrode switch on the ground. Then, the collection station is connected to the other end of the segmented cascading cable to form a resistivity sensing node. The connection between the cable and the collection station is shown in FIG. 2d.

Wherein, the segmented cascading ERT cable carries 8-10 electrodes, and the centralized ERT wellhole cable is a watertight integrally molded cable containing 30-60 electrode structures.

The collection station consists of a control module, power supply module, potential measurement module, communication module, and GPS module. The collection station performs power supply or potential measurement tasks according to the instructions of the edge node to which it belongs. The communication module relies on mobile communication technology to handle communication between the collection station and its affiliated edge node. The control module, under the command of the edge node, controls the operation, self-check, communication with the edge node, and the role swapping (power supply/potential measurement) under the control of the measurement instructions, channel selection, execution of the measurement process, and control of various modules in a series of processes for the system's self-management.

The power supply module, upon receiving the power supply command issued by the edge node, selects the corresponding electrode channel through the control module and supplies power to the underground through the connected ERT cable and electrodes, while measuring the power supply current. After the power supply is completed, it uploads the node's power supply channel number, measurement start time, and power supply current value.

The potential measurement module, upon receiving the potential measurement command issued by the edge node, selects the corresponding electrode channel through the control module and performs potential measurement through the connected cable and electrodes, simultaneously measuring the potential difference. After the measurement is completed, it uploads the node's potential channel number, measurement start time, and potential difference value. When power supply and potential measurement belong to different sensing nodes, the measurement start time is coordinated by the edge node (synchronized by GPS). When power supply and potential measurement belong to the same node, the start time of power supply and potential measurement is coordinated by the collection station's own program.

The communication module uses a 5G or higher mobile communication module, supporting MEC edge access and edge computing modes. It directly controls the collection process and coordinates the selection of power supply/potential measurement channels between various sensing nodes through the edge server. After the measurement is completed, the collection result data is directly uploaded through the mobile communication network and stored in the edge server.

The GPS module is configured for accurate timing of each node. The coordination between different nodes during the power supply/potential measurement process is efficiently and easily achieved using the precise timing of GPS satellites. The GPS module includes a GPS antenna and its interface connection line.

b. Edge Computing Layer

The resistivity sensing nodes, as independent data acquisition units, are equal and operate independently, but they need to collaborate to perform combined measurements (power supply/potential measurement) between different nodes to achieve imaging across streets. Coordination between different sensing nodes requires a higher-level control unit for planning and coordination. The traditional solution is to design a central control console to remotely control all sensing nodes through the network. However, when there are many sensing nodes, issues such as network congestion and delay may arise, impacting real-time performance, reliability, and collection efficiency. The centralized control mode of the central control console appears to be inadequate and difficult to sustain. Therefore, it is necessary to “sink” the collection control, move it forward to multiple mobile edge servers close to the collection nodes, forming a distributed edge control node for near deployment and control.

The edge nodes are set up and configured by the central cloud computing platform, forming multiple edge servers distributed throughout the sensing network. Each edge server coordinates the work of multiple sensing nodes within its control domain. The tasks of the edge nodes mainly include: (1) Data collection, coordinating and controlling the selection of power supply and potential measurement electrode pairs within the control domain and controlling the collection process. (2) Data storage and transmission, filtering and organizing the data collected within the domain, storing it in the edge cloud in the designed format, and uploading the data to the central cloud for backup, for subsequent centralized processing of the global dataset. (3) Preliminary data processing, after data collection is complete, comparing and analyzing real-time data with historical data and the model obtained based on historical data (the results of the regional model calculation feedback from the central cloud to the edge nodes). If there are abnormal changes, report the abnormal information to facilitate further comprehensive analysis and processing by the central cloud computing platform.

The edge cloud layer is also the network transmission layer where distributed wireless networks converge and concentrate into wired public networks. It uses a combination of wireless mobile communication networks and wired internet to achieve remote data transmission and collection instruction delivery. The mobile communication network requires the use of a communication platform of 5G or above. By using edge servers for near control, it achieves distributed, near-efficient control of collection nodes, as well as distributed storage of collected data.

The mobile communication network has unparalleled mobility and flexibility compared to wired networks. It is particularly suitable for dynamically increasing or decreasing sensing nodes and adjusting the positions of sensing nodes. Moreover, data transmission is through nearby base stations (distributed), avoiding channel congestion in wired transmission. The partitioned and distributed network structure of mobile cellular base stations is highly consistent with the partitioned and distributed layout of sensing nodes, facilitating smooth transmission of instructions and data. The advantage of using mobile communication networks for remote data transmission is that it can make full use of the existing public communication network, avoiding duplicate investment in wired sensing network construction, significantly saving costs and financial investment. It also leverages efficient and stable public network resources, achieving seamless integration of wireless and wired networks and avoiding the later operational and maintenance costs of a self-built network transmission layer.

c. Central Cloud Computing Layer

Central cloud computing relies on the resources of a general public cloud computing platform and, compared to the edge cloud, the large-scale parallel computing capability of the central cloud is particularly suitable for high-performance computing needs such as processing massive sensing data. It is configured for the storage and intelligent processing analysis of the entire resistivity sensing data.

The main tasks of the central cloud include: (1) Overall operation management of the sensing network, including setting and configuring distributed edge servers, and then managing all resistivity sensing nodes through edge servers. (2) Global data processing and model inversion, including comparing and mining real-time data and historical data, and sending model results to edge servers to guide preliminary data analysis. (3) Data abnormality alarm beyond the threshold, reporting to the city's brain for comprehensive analysis and disposal of multi-source data.

Therefore, the construction of a complete and feasible resistivity sensing system is achieved through the coordination and cooperation of the central cloud, edge cloud, and sensing nodes. The coordination between the central cloud and edge cloud is constrained and task-assigned through the federated computing paradigm. The coordination between the central cloud, edge cloud, and among edge clouds is achieved through cloud-edge-end collaboration and games in the federated computing paradigm, dynamically configuring task goals, realizing collaboration and division of labor, and jointly maintaining and ensuring the normal operation of the entire system and bidirectional data flow (information feedback).

The city's brain is also built based on the central cloud, relatively speaking, it receives the convergence of multi-source data and has higher data integration and intelligent decision support capabilities. It is the ultimate export of the sensing results of the present invention.

### II. Data Collection Method

### 1. Arrangement of Resistivity Sensing Nodes

The deployment of resistivity sensing nodes primarily revolves around the placement of electrodes, offering two main configurations: surface-level horizontal placement and vertical wellbore placement. Factors such as electrode spacing, total electrode count, cable layout, positioning of collection stations (involving external power supply), and the arrangement of mobile communication antennas and GPS antennas need comprehensive consideration. In horizontal deployment, segmented cables are shallowly buried along the green belts or sidewalks on both sides of the streets. Wellbore cables are drilled and positioned at suitable locations near intersections or road sides, with a symmetrical layout recommended on both sides of the road (taking care to avoid buried pipelines). The recommended length of wellbore cables is 30 m to 60 m, with an electrode spacing of 0.5 m to 1 m. The positioning of horizontal electrode points adheres to the principle of random distributed pole layout, where no specific requirements are imposed on electrode spacing and positioning. When conditions permit, an attempt is made to achieve a uniformly distributed layout. Upon completion of electrode point placement, utilize GPS, total stations, and other surveying equipment to promptly collect the three-dimensional geographical coordinates of each electrode point, which are then input into the system for subsequent data collection and processing.

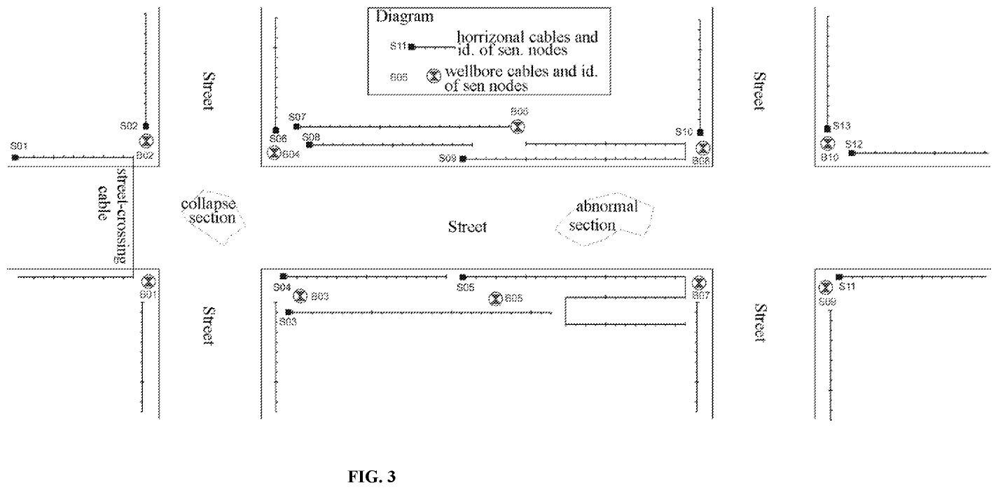

Because collection station power supply necessitates the use of city electricity boosting, the positioning and construction of collection stations need to be designed based on the conditions on both sides of the street. Fixed equipment boxes are established for city electricity power access, placements of boost power supplies and collection stations. Multiple nearby collection stations can consider sharing a common equipment box (as shown in FIGS. 3, B03, S03, S04, and B04, S06, S07, and S08).

Horizontal cables can be configured as single lines, U-shaped double lines, or S-shaped multiple lines. In FIG. 3, S02, S03, S06 are shown as single lines, S01, and S09 are U-shaped double lines. Specifically, S01 is configured as a U-shape connecting the sidewalks on both sides of the street through a cross-street cable, while S14 is a U-shaped double line placed on a single side of the street. In instances where there is a certain open space on one side of the street, an S-shaped multi-line (S05 line in FIG. 3) arrangement can be implemented. The positions, spacing, and length of electrodes on the measurement line can be arbitrarily arranged based on requirements, as long as the connection between the start and end is maintained. The tail end of the horizontal cable can also be connected to the wellbore cable to form an integrated well and surface sensing node for a single collection station. For example, in FIGS. 3, S07 and B06 can be independently measured using separate collection stations or B06 wellbore cable can be connected to the tail end of S07 to save on B06's collection station. The advantage of well and surface connection is that wellbore electrode measurement is directly completed within the S07 collection station, seamlessly connecting with more combined measurement methods. The downside is that with more measurement points, the collection time is relatively extended.

### 2. Collection Parameter Configuration

This invention employs a random dipole device as a unified device type, encompassing regular device types such as Wenner, Schlumberger, dipole-dipole, as well as various asymmetric and non-collinear device types. Therefore, the random dipole device serves as the normalized expression for all device types, with dynamically adjustable dipole moments and electrode spacing parameters, offering wide adaptability and flexibility. This is conducive to flexibly meeting the requirements of complex and specific observation settings (crossing roads, branching, and uneven electrode settings). Additionally, dipole-dipole devices exhibit high detection resolution. In addition to device type settings, collection parameter configuration significantly influences the resolution and exploration depth of actual measurements. Therefore, appropriate collection parameters need to be designed to achieve optimal detection results.

### (1) Optimal Electrode Spacing

Electrode spacing refers to the distance between electrodes placed in front and behind in the electrode arrangement. In a random distribution system, the actual electrode positions can fluctuate based on surface conditions. Since electrode spacing determines exploration depth, imaging resolution, and system construction costs, although electrode spacing can vary, there remains an optimal range of electrode spacing values, taking into account the balance between exploration depth and resolution. When implementing actual electrode point placement, it is recommended to reference optimal electrode spacing for polarization.

### (2) Maximum Isolation Coefficient

Assuming the electrode spacing is p, the distance between the power supply and potential measurement points can range from p, 2p, 3p, 4p up to the maximum arrangement interval N*p (N is the number of electrode channels in the instrument system). However, in actual measurements, a maximum isolation coefficient (m<=N) is often set based on estimating the maximum exploration depth h:

m=h/(λ×p) (1)

Where, λ=2-3. During data collection, the distances between the power supply electrode pair AB and potential measurement electrode pair MN, including the dipole moment and electrode spacing, are increased sequentially in order from isolation coefficient 1 to m. This involves traversing all possible ABMN position combinations.

### (3) Effective Measurement Radius

Due to the joint detection and monitoring of well and surface, the distribution of power supply and potential measurement points in three-dimensional space, as well as the effective measurement radius, need consideration. Given the non-uniformity of underground media, differences in the effective measurement range may exist when points are in different media. Therefore, the effective measurement range for well and surface joint measurement is not a perfect, symmetrical spherical space. Considering that the effective measurement range is also influenced by factors such as instrument measurement accuracy and power supply current, which have certain flexible variation space, it can still be simplified into an “effective measurement spherical domain” to filter measurement points, improving measurement efficiency and effectiveness. The radius of the “effective measurement spherical domain” is the effective measurement radius R. Outside the effective measurement radius R, the potential difference decreases rapidly with increasing electrode spacing of the dipole-dipole device, quickly falling below the instrument's effective measurement accuracy. R≤n*a (where n is the effective radius coefficient, a is the dipole moment of the power supply electrode pair). Generally, n=6-8. This invention adopts a dynamic dipole moment measurement design, effectively improving instrument reading accuracy. Therefore, the recommended range for the actual sensing radius coefficient n is between 6 and 14. The purpose of setting an effective radius is to set a measurement threshold based on the effective measurement radius during actual data collection, excluding most measurement processes beyond the effective measurement radius, improving data collection efficiency.

During the measurement process, it is essential to dynamically calculate the distances between the power supply electrodes AB and the measurement electrodes MN in real-time using the following formula:

Assuming the coordinates of points A and B are respectively (x_{A}, y_{A}, z_{A}) and (x_{B}, y_{B}, z_{B}), then the coordinates of the midpoint O of AB are:

x_{O}=(x_{A}+x_{B})/2 y_{O}=(y_{A}+y_{B})/2 z_{O}=(z_{A}+z_{B})/2 (2)

Assuming the coordinates of points M and N are respectively (x_{M}, y_{M}) and (x_{N}, y_{N}), then the coordinates of the midpoint O₁ of MN are:

x_{O1}=(x_{M}+x_{N})/2 y_{O1}=(y_{M}+y_{N})/2 z_{O1}=(z_{M}+z_{N})/2 (3)

Then distance L between O and O₁ is:

L=\sqrt{(x_{O}−x_{O1})²+(y_{O}−y_{O1})²+(z_{O}−z_{O1})²} (4)

Subsequently, a comparison is made with the predefined effective measurement radius, and any MN points exceeding this radius will have their measurements canceled, expediting the data collection process.

### 3. Selection of Power Supply Electrode Pairs and Measurement Electrode Pairs

Throughout the data collection process of this invention, because the system supports the non-uniform, random distribution of measurement points, the distances between AB and MN will increase with the isolation coefficient (multiples of electrode spacing). It is necessary to pre-locate and measure all measurement point positions before collection, calculate the effective measurement radius that dynamically changes during the measurement process based on the positions of ABMN, and control the point selection process.

The entire measurement process of this invention unfolds around the power supply process, iterating through all possible power supply electrode combinations within each sensing node (power supply electrode pair AB). For each power supply combination, iterate to find all possible potential measurement electrode combinations corresponding to the power supply electrode pair AB (potential measurement electrode pair MN) within the effective measurement spherical domain of the power supply node or surrounding nodes, achieving One-supply Multiple-measurement. The measurement process traverses all power supply points in order of edge node number and sensing node number, continuing until the last power supply point is measured, completing a single data collection process for the entire measurement area. The measurement process is then repeated at set time intervals, realizing dynamic four-dimensional sensing. When an anomaly is detected in a specific area, observation frequency can be adjusted, and encrypted measurements can be performed for the entire area or the abnormal section (edge node setting). This can be done in coordination with other detection methods and on-site inspections for anomaly verification.

### Specific Execution Process:

(1) The central cloud computing platform sequentially selects different edge nodes for partitioned measurements (the selected edge nodes are active nodes, while others remain inactive in a dormant state). The chosen edge node, as an active node, selects a sensing node in sequential order as the power supply node. It then selects an electrode combination within the sensing node as the power supply electrode pair AB, and an electrode combination within the edge node domain as the measurement electrode pair MN. Additionally, the MN electrode pair belongs to the same sensing node. The process checks if the distance between the measurement electrode pair MN and AB is within the effective measurement radius r of AB. If yes, power supply and potential measurements are conducted; if not, it moves to the next ABMN combination for a new measurement condition check. This process continues until all possible power supply electrode pairs and potential measurement electrode pairs within that sensing node are traversed, completing the power supply and potential measurement process for that sensing node acting as the power supply node.
(2) Sequentially move to the next resistivity sensing node to execute the power supply and potential measurement process, continuing until all combinations of electrode pairs supplying power to the last sensing node are completed, marking the end of the power supply and measurement process for the current edge node.
(3) Proceed to the next edge node, executing the same power supply and measurement process until all edge nodes are traversed.

Additionally, to ensure comprehensive data collection and improve the clarity of underground space imaging, the electrode distance (AB) is continuously varied as follows when selecting power supply electrode pairs:
(1) Sequentially choose sensing nodes as power supply nodes in order from the edge node. The power supply electrode pair AB is selected only within that sensing node. The selection of points A and B follows the principle of increasing electrode point numbers. It starts from the end near the collection station (starting point), with the closest electrode point to the collection station chosen as electrode A. Electrode B is selected at a sequence interval equal to 1. Then, keeping the sequence interval of AB, A and B are shifted to the next electrode point until point B reaches the last electrode point in the current sensing node. This process completes all power supplies where the sequence interval of AB is equal to 1.
(2) Starting from the beginning, select points A and B with a sequence interval of 2 for power supply, then shift A and B until point B reaches the last electrode point. This process completes power supply with a sequence interval of 2 between A and B.
(3) Repeat changing the sequence interval of AB until the set maximum isolation factor is reached, completing the power supply process for that sensing node. Then, choose the next sensing node and repeat the power supply point selection process, implementing power supply.

Each power supply is initiated by the edge node, setting the start time and power supply parameters. After power supply completion, save the power supply electrode numbers, start time, and power supply current values. Upon completion of the entire measurement, upload the entire dataset to the edge node for processing and sorting.

Moreover, to enhance data collection speed, this invention employs two collection methods for processing measurement electrode pairs within nodes and between nodes:
(1) Intra-node Sequential Measurement: Within a single node, during each power supply, one measurement electrode pair MN is sequentially selected according to the MN order table for potential measurement. Subsequently, other paired MN sets are chosen for the next power supply and potential difference measurement. Each time a measurement is conducted, one of the various MN combinations within a node needs to be selected in sequence for the measurement process.
(2) Inter-node Simultaneous Measurement: When MN is located in nodes other than those containing AB, during each measurement with AB supplying power, MN in different nodes simultaneously undergo potential measurement. Coordinated by GPS timing, multiple electrode pairs MN and power supply electrode pair AB work simultaneously between different nodes, achieving One-supply Multiple-measurement.

Once again, the data collection process of this invention can utilize the simultaneous power supply and search for potential measurement points. Although this method is feasible, its efficiency is too low, involving a considerable amount of redundant calculations and a blind search process, severely impacting data collection efficiency. Therefore, the efficiency can be improved by creating a collection table in advance: Once the electrode point positions are fixed and have accurate location coordinates after the sensing nodes are set up, the edge node can calculate and create a collection table in advance for power supply and potential measurement. The table lists the node numbers, electrode numbers corresponding to power supply points AB, and node numbers and electrode numbers corresponding to potential measurement points MN. Since there is a one-to-many relationship between power supply and potential measurement, the table corresponds to a power supply electrode pair AB and has multiple potential measurement electrode pairs MN. MNs belonging to the same sensing node are placed in columns, and potential measurement points belonging to different sensing nodes are placed in rows according to node numbers. During actual data collection, for each power supply point AB, MN electrode pair numbers are sequentially extracted from different nodes and simultaneously undergo potential measurement. After completion, save the node number, electrode number, collection time, and potential difference value. Then move to the next column, extract MN electrode pairs corresponding to that column, notify power supply point AB for power supply, and inform the corresponding node to measure potential with the specified electrode numbers, recording and saving the results. The pointer is then moved to and extracts the next column of MN electrode pairs for potential measurement until the MN column is empty, completing the power supply process for that AB electrode pair. Move to the next power supply point in the collection table and repeat the process until the last potential measurement point for the last power supply point in the collection table is measured, completing the entire data collection process for that edge node.

In case of sensing node updates (addition or removal of sensing nodes), submit the update information, recalculate the collection table for the updated measurement process. Using this table significantly reduces the computational workload and search time at the collection station, improving data collection efficiency.

### 4. Uploading and Storing Measurement Data

Upon completion of the collection work, the edge node notifies each sensing node to upload all the data for this session. The edge node organizes the data uploaded by each sensing node in chronological order. The uploaded data from each node includes both power supply and potential measurement data. It needs to be cross-referenced with time and the collection table to form an electronic spreadsheet as follows: Edge node number, sensing node number, measurement time, power supply point A number, power supply point B number, measurement point M number, measurement point N number, power supply current I, potential difference V, device factor K, and apparent resistivity Ps. The device factor K and apparent resistivity Ps are calculated based on the ABMN position coordinates, power supply current I, and potential difference V, and are then added to the table to create a comprehensive measurement data information table.

### 5. Data Processing and Data Mining (Artificial Intelligence Cloud Computing)

Artificial intelligence tailored for big data permeates the entire data flow process in the resistivity sensing system. It starts with intelligent edge cloud competition, coordination, and optimized configuration based on federated computing. This leads to automatic optimization management of the data collection process in sensing nodes. The central cloud, relying on big data and machine learning, engages in data mining and intelligent analysis, constructing perception models for swift and automatic anomaly identification.

The distinctive feature of this invention lies in the bidirectional feedback intelligent flow of data among the various components within the constructed system: Sensing nodes are controlled by edge nodes, while simultaneously sending their own status information and collected data promptly to edge nodes. This facilitates edge nodes to adjust collection parameters and update data collection frequency in a timely manner. Edge nodes report the preliminary processed analysis results to the central cloud's data center. The data center, based on historical data and intelligently analyzed model results from various sources, provides feedback to distribute results to edge nodes, guiding them in rapid anomaly analysis and risk identification. The city's brain receives model prediction results and warning information from the data center and combines it with other multi-source data for scientific analysis and decision-making. Simultaneously, it sends back other multi-source data and its historical information to the data center, aiding in model calibration and enhancement.

### 6. Multi-Source Data Analysis and Smart Decision-Making

Accumulating over time, the sensing system gathers a vast amount of apparent resistivity data. However, apparent resistivity merely represents a comprehensive reflection of underground and spatial structural resistivity. To obtain resistivity imaging results, resistivity inversion is required. Three-dimensional and four-dimensional resistivity imaging demands substantial computational resources and machine hours. Conducting comprehensive data inversion on a large scale is neither economical nor practical. Therefore, this invention employs artificial intelligence algorithms in the cloud to intelligently analyze and mine big resistivity data. It identifies and discovers areas and points with significant variations, followed by detailed four-dimensional inversion of the anomalous sections. This helps understand the temporal characteristics of changes in anomalous sections, eliminating factors like weather. For critical anomalous areas, the sensing measurement frequency is increased. If there is a trend of accelerated changes or expanded scope, the risk assessment mode is activated: 1. Further increase measurement frequency for dynamic real-time observation. 2. Conduct on-site verification and confirmation, including on-site drilling validation and other geophysical methods (radar, electromagnetic, or seismic exploration). If on-site verification rules out anomalies, analyze the reasons and modify the model and alarm threshold for that section. If on-site verification confirms anomalies, report to the city's brain, initiate multi-source data analysis and an expert system to determine the source and cause of anomalies, and submit to the decision-making command system for emergency response. Simultaneously, utilize this as a successful case for training datasets to optimize models and improve predictive effectiveness.

What is claimed is:

1. An urban underground space resistivity sensing system based on cloud-edge-end collaboration, wherein the system adopts a cloud-edge-end architecture design comprising a central cloud computing platform, a plurality of edge servers connected to the central cloud computing platform through a distributed network, and a plurality of resistivity sensing nodes connected to each edge server through a distributed network;
the central cloud computing platform is configured to manage the entire resistivity sensing system, comprising: setting up and configuring distributed edge servers, managing all resistivity sensing nodes through edge servers; conducting overall data processing and model inversion, comprising: comparing and analyzing real-time data and historical data, sending model results to the edge servers to guide preliminary data analysis; and issuing alerts and reports for data exceeding thresholds;
the edge server, serving as an edge node, is responsible for coordinating the collaborative work of multiple resistivity sensing nodes within a controlled domain of the edge server, comprising: coordinating and controlling a selection and collection process of power supply and potential measurement electrode pairs within the control domain; filtering, organizing, and storing the collected data within the control domain in a designed format, simultaneously uploading the data to the central cloud computing platform for backup; after completing data collection, comparing and analyzing real-time data, historical data, and the model calculation results for the region fed back by the central cloud computing platform based on historical data to detect anomalies; if anomalies are detected, reporting, by the edge server, the abnormal information to the central cloud computing platform;
the resistivity sensing node, serving as an end node, is horizontally placed along city roads and/or vertically placed in wellbores; each resistivity sensing node is an independent resistivity sensor unit, including a data collection station, a multi-channel electrode conversion switch connected to the data collection station, a multi-core electrical resistivity tomography (ERT)cable, and a grounding electrode connected to the multi-core ERT cable; the power supply or potential measurement tasks are performed by the resistivity sensing node according to the instructions of the edge node associated with the resistivity sensing node, and the measurement data is uploaded by the resistivity sensing node to the corresponding edge node.

2. The system according to claim 1, wherein when resistivity sensing nodes are horizontally placed along city roads, the cables in the resistivity sensing nodes are multi-core segmented cascaded ERT cables; the segmented cascaded cables are serially connected into a single cable through a cascaded electrode conversion switch, with the data collection station connected to one end of the complete cable;
when the resistivity sensing nodes are vertically placed in wellbores, the cables in the resistivity sensing nodes are single centralized high-density electrical cables in which a plurality of electrode structures are evenly spaced; each electrode structure serves as a grounding electrode, and the top of the cable is connected to the data collection station through a centralized electrode switch;
when the resistivity sensing nodes are placed both horizontally along city roads and in wellbores, the single centralized high-density electrical cable in the wellbore is first connected to one end of the multi-core segmented cascaded high-density electrical cable on the ground through a centralized electrode conversion switch; the data collection station is connected to the other end of the segmented cascaded ERT cable; a plurality of electrode structures are evenly spaced on the centralized ERT cable, each serving as a grounding electrode.

3. The system according to claim 1, wherein the data collection station comprises a control module, a power supply module, a potential measurement module, a communication module, and a GPS module;
the control module, under the command of the associated edge node, is configured to manage the operation of the data collection station's system, including self-management, self-checking, communication with edge nodes, functional interchange between power supply and potential measurement under control of collection instructions, channel selection, execution of the collection process, and data storage and upload of measurement data;
the power supply module, upon receiving a power supply command, is configured to select the corresponding electrode channel through the control module, supply power to the underground through the connected cable channel and electrodes, measure the power supply current magnitude, and upload the node's and power supply channel's identification, measurement start time, and power supply current value after completing the power supply;
the potential measurement module, upon receiving a potential measurement command, is configured to select the corresponding electrode channel through the control module, perform potential measurement through the connected cable channel and electrodes, and measure the potential difference, and upload the node's and potential measurement channel's identification, measurement start time, and potential difference value;
the GPS module is configured for precise time synchronization and coordination of all nodes.

4. The system according to claim 1, wherein the edge nodes is communicated remotely with end nodes through a mobile communication network, and the edge nodes is communicated remotely with the central cloud computing platform through a wired network.

5. A method for collecting urban underground space resistivity data based on cloud-edge-end collaboration, wherein the method is implemented by the system of claim 1, comprising the following steps:
(1) determining an arrangement and collection parameters of resistivity sensing nodes based on actual conditions of a target street, a maximum exploration depth, and a resolution of underground detection targets;
(2) arranging the resistivity sensing nodes on the target street; a unique system identification is assigned, by the central cloud computing platform, to each edge node, and a unique system identification is assigned, by each edge node, to each resistivity sensing node within the domain of the edge node; a unique system identification is assigned, by the sensing node, to each electrode point in the sensing node; collecting three-dimensional geographic coordinates of each electrode point;
(3) sequentially selecting, by the central cloud computing platform, different edge nodes for block measurements; the selected edge node, in sequence according to the system identification of resistivity sensing nodes; selecting one sensing node as a power supply node, and then selecting one electrode combination within the sensing node as a power supply electrode pair AB, and selecting an electrode combination within the domain of the edge node belonging to the sensing node as a potential measurement electrode pair MN; wherein the potential measurement electrode pair MN belongs to a same sensing node; determining whether a distance between the measurement electrode pairs MN and AB is within an effective measurement radius r of AB; if yes, performing power supply and potential measurement; if no, moving to the next ABMN combination position for a new measurement condition judgment; the effective measurement radius of AB is given by r≤n·a, where n is the effective radius coefficient, n=6−14, and a is the distance between A and B; traversing all power supply electrode pairs and the plurality of paired potential measurement electrode pairs within the sensing node, and completing the power supply and potential measurement process when the sensing node acts as the power supply node;
(4) sequentially moving to the next resistivity sensing node and performing the power supply and potential measurement process until all power supply electrode combinations for the last sensing node are completed, thereby finishing the entire power supply and potential measurement process for the current edge node;
(5) proceeding to the next edge node and performing the same power supply and potential measurement process until all edge nodes have been traversed.
(6) after completing the data collection, the edge node is configured to notify each sensing node to upload the collected data and its own status information; the edge node is configured to format the data within the domain, quickly compare the data with the region model results downloaded from the central cloud computing platform, and provide processing analysis results; the edge node is configured to report the preliminary processing and analysis results to the central cloud computing platform; the central cloud computing platform, based on historical data and intelligent analysis model results from other sources, is configured to feedback and distribute the results to each edge node to guide subsequent edge nodes in rapid anomaly analysis and risk identification.

6. The method according to claim 5, wherein when AB serves as the power supply electrode pair, and the GPS module is configured to coordinate timed parallel measurement of potential measurement electrode pair MN which is positioned different nodes and satisfies conditions, namely, multiple potential measurement electrode pairs MN at different nodes parallelly work with one power supply electrode pair AB, and thus achieving One-Supply Multiple-Measurements simultaneously.

7. The method according to claim 5, wherein when selecting the power supply electrode pair AB, follow the principle of increasing electrode numbers and start from the end where the collection station is located; selecting the electrode A as the closest electrode point to the collection station, and selecting the electrode B with a sequence number interval of 1 as the power supply electrode pair AB; maintaining the sequence number interval of AB, shifting A and B to the next electrode point until point B reaches the last electrode point of the current sensing nodes, and completing all power supply processes with AB sequence number interval equal to 1;
starting from the beginning and select points A and B with a sequence number interval of 2 for power supply; shifting A and B until point B reaches the last electrode point, and completing the power supply process with a sequence number interval of 2 between A and B; and
repeating to change the interval between A and B until the set maximum isolation coefficient is reached, completing the power supply process for that sensing node.

8. The method according to claim 5, wherein once the resistivity sensing nodes are arranged, and the positions of each electrode point are fixed with accurate coordinates, the corresponding edge node calculates and creates a power supply and potential measurement collection table in advance; the table orderly comprises a sensing node number and an electrode number of each power supply point AB, as well as the sensing node number and electrode number of the plurality of potential measurement points MN, ensuring that the actual collection is executed in the order of the table, and completing the entire data collection process.
